(19) United States
(12) Patent Application Publication
(10) Pub. No.: US 2023/0227970 A1
(43) Pub. Date: Jul. 20, 2023

(54) REMOVAL OF TIN OXIDE IN CHAMBER CLEANING

(71) Applicant: Lam Research Corporation, Fremont, CA (US)

(72) Inventors: Jeongseok Ha, Portland, OR (US); Pei-Chi Liu, Portland, OR (US)

(21) Appl. No.: 18/001,590

(22) PCT Filed: Jun. 10, 2021
(86) PCT No.: PCT/US2021/036763

§ 371 Date: Dec. 12, 2022

Related U.S. Application Data
(60) Provisional application No. 62/705,189, filed on Jun. 15, 2020.

(51) Int. Cl. C23C 16/44; C23C 16/40; C23C 16/455; C23C 16/50; H01L 21/311

(52) U.S. Cl. CPC C23C 16/4405; C23C 16/407; C23C 16/45536; C23C 16/50; H01L 21/31122; H01L 21/31144

(57) ABSTRACT

Process chambers are cleaned from tin oxide deposits by a method that includes a step of forming a volatile tin-containing compound by exposing the tin oxide to a mixture of hydrogen (H₂) and a hydrocarbon in a plasma, followed by a step that removes a carbon-containing polymer that formed as a result of the hydrocarbon exposure. The carbon-containing polymer can be removed by exposing the carbon-containing polymer to an oxygen-containing reactant (e.g., to O₂ in a plasma), or to H₂ in an absence of a hydrocarbon. These steps are repeated as many times as necessary to clean the process chamber. The method can be used to clean ALD, CVD, and PVD process chambers and is particularly useful for cleaning at a relatively low temperature of less than about 120° C.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD OF THE INVENTION

This invention pertains to methods and apparatuses for cleaning process chambers. Specifically, embodiments of this invention pertain to removal of tin oxide deposits from process chambers used in semiconductor device manufacturing.

### BACKGROUND

In semiconductor device fabrication, deposition and etching techniques are used for forming patterns of materials, such as for forming metal lines embedded in dielectric layers. Deposition techniques include atomic layer deposition (ALD), chemical vapor deposition (CVD), and physical vapor deposition (PVD). Etching techniques include wet etching methods and dry etching methods, such as reactive ion etching (RIE).

Dry deposition and etching methods are typically carried out in process chambers having a substrate support for holding a semiconductor substrate in place during deposition or etching, and an inlet (e.g., a showerhead) for introducing one or more process gases to the process chamber. The deposition and etching apparatuses may also include a system for generating a plasma either directly in the process chamber housing the substrate, or upstream from the process chamber. The process chambers can be periodically cleaned to remove deposits of materials from the chambers, such as from chamber walls and showerheads.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods and apparatuses for removal of tin oxide deposits from process chambers are provided. The methods are particularly useful for cleaning tin oxide at a relatively low temperature (e.g., at a temperature of less than about 140° C., such as at a temperature of about 30-120° C.), but can be used at higher temperatures as well. The methods can be used for removing tin oxide in a variety of process chambers including but not limited to ALD process chambers (including plasma enhanced ALD process chambers), CVD process chambers (including plasma enhanced CVD process chambers), and PVD process chambers.

In one aspect, a method of cleaning a process chamber is provided, where the method includes: (a) providing a process chamber having a layer of tin oxide on at least some parts of the process chamber; (b) exposing the tin oxide layer in the process chamber to a process gas that includes a hydrocarbon and hydrogen (H₂) to convert at least a portion of the tin oxide layer to a volatile compound, wherein the exposure of the tin oxide layer to the process gas that includes a hydrocarbon and hydrogen (H₂) further results in a formation of a non-volatile carbon-containing polymer and, optionally, purging the process chamber; and (c) removing the carbon-containing polymer by exposing the carbon-containing residue to an oxygen-containing reactant or to H₂, wherein exposure to H₂ is performed in an absence of hydrocarbon. The method can also involve repeating steps (b) and (c) in an alternating fashion.

In one embodiment the carbon-containing polymer is removed in by exposing the carbon-containing residue to the oxygen-containing reactant. Examples of oxygen-containing reactants include without limitation O₂, O₃, and H₂O₂. In one embodiment the oxygen-containing reactant is plasma-activated O₂. In another embodiment the oxygen-containing reactant is O₃.

In another embodiment the carbon-containing polymer is removed by exposing the carbon-containing residue to a process gas consisting essentially of H₂ or consisting essentially of a mixture of H₂ and an inert gas in a plasma.

The removal of the carbon-containing polymer in some embodiments is conducted while the process chamber is heated.

In some implementations the process chamber includes metal parts, such as aluminum parts, which are cleaned by the provided methods.

In another aspect, an apparatus for processing a semiconductor substrate is provided, where the apparatus includes a process chamber having an inlet for introduction of a process gas, and a controller having program instructions for cleaning the process chamber from a tin oxide layer. In one embodiment, the program instructions are configured for causing: (i) an exposure of the tin oxide layer in the process chamber to a process gas comprising a hydrocarbon and hydrogen (H₂) to convert at least a portion of the tin oxide layer to a volatile compound, wherein the exposure of the tin oxide layer to the process gas comprising a hydrocarbon and hydrogen (H₂) further results in a formation of a non-volatile carbon-containing polymer; and (ii) a removal of the carbon-containing residue by exposing the carbon-containing polymer to an oxygen-containing reactant (e.g., at least one of O₂, O₃, and H₂O₂), or to H₂, wherein exposure to H₂ is performed in an absence of hydrocarbon. In one embodiment the apparatus further includes a system for generating a plasma. In some embodiments the program instructions for (ii) are configured to cause an exposure of the carbon-containing polymer to plasma-activated O₂. In some embodiments the apparatus further includes a heater. In some embodiments the program instructions for (ii) are configured to cause an exposure of the carbon-containing polymer to plasma-activated O₂ in a heated process chamber. In some implementations the program instructions are further configured to repeat steps (i) and (ii). In another aspect, the controller includes program

In another aspect, a computer machine-readable media is provided, where the media includes code for performing any of the methods described herein.

In another aspect, a method for etching a tin oxide layer on a semiconductor substrate is provided, where the method includes: (a) providing a semiconductor substrate having an exposed layer of tin oxide; (b) contacting the exposed tin oxide layer in a process chamber to a process gas comprising a hydrocarbon and hydrogen (H₂) to convert at least a portion of the tin oxide layer to a volatile compound, wherein the contacting of the tin oxide layer to the process gas comprising a hydrocarbon and hydrogen (H₂) further results in a formation of a non-volatile carbon-containing polymer; and (c) removing the carbon-containing polymer by exposing the carbon-containing polymer to an oxygen-containing reactant or to H₂, wherein exposure to H₂ is performed in an absence of hydrocarbon. In some embodiments, the method further includes applying the photoresist to the semiconductor substrate; exposing the photoresist to light; patterning the photoresist and transferring the pattern to the semiconductor substrate; and selectively removing the photoresist from the semiconductor substrate.

In some embodiments the method further includes, prior to etching, depositing tin oxide on the semiconductor substrate (which may also involve deposition on the process chamber) using a tin-containing precursor selected from the group consisting of SnF₂, SnCl₄, SnBr₄, SnH₄, tetraethyl tin (SnEt₄), tetramethyl tin (SnMe₄), tetrakis(dimethylamino)tin (Sn(NMe₂)₄), tetrakis(diethylamido)tin (Sn(NEt₂)₄), tetrakis(ethylmethylamino)tin (Sn(NMeEt)₄), (dimethylamino)trimethyltin(IV) (Me₃Sn(NMe₂)), dibutyltin diacetate (Bu₂Sn(OAc)₂), Sn(II)(1,3-bis(1,1-dimethylethyl)-4,5-dimethyl-(4R,5R)-1,3,2-diazastannolidin-2-ylidene), N², N³-di-tert-butyl-butane-2,3-diamino-tin(II), bis[bis(trimethylsilyl)amino]tin(II)

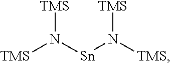 [SMILES: C[Si](C)(C)[N]([Sn][N]([Si](C)(C)C)[Si](C)(C)C)[Si](C)(C)C]

where TMS is trimethylsilyl,

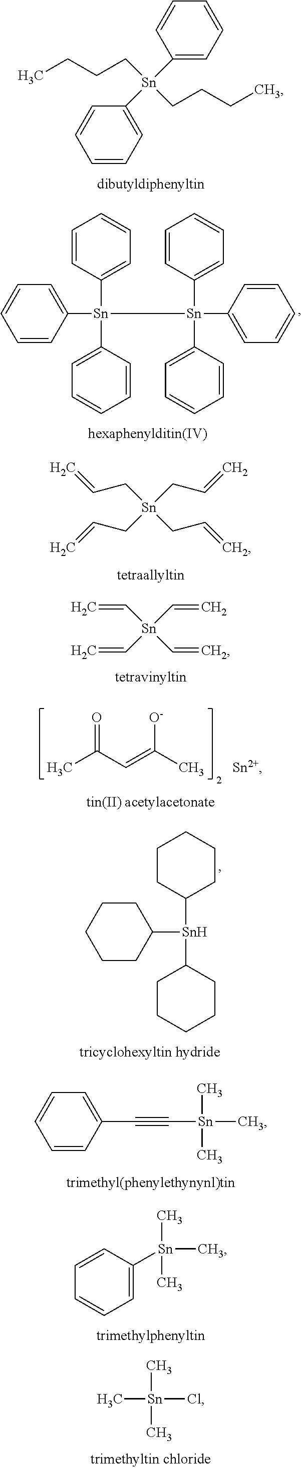

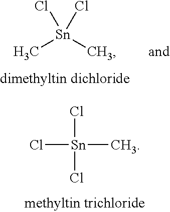

In some embodiments the tin-containing precursor is an organotin precursor selected from the group consisting of tetramethyl tin, tetrakis(dimethylamino)tin, and (dimethylamino)trimethyl tin(IV).

These and other aspects of implementations of the subject matter described in this specification are set forth in the accompanying drawings and the description below.

### BRIEF DESCRIPTION OF THE DRAWINGS

FIG. 1 is a process flow diagram for a chamber cleaning method according to an embodiment provided herein.

FIG. 2 is a process flow diagram for a chamber cleaning method according to an embodiment provided herein.

FIGS. 3A-3D provide schematic cross-sectional views of a portion of a process chamber during cleaning, according to an embodiment provided herein.

FIG. 4 is a schematic presentation of an ALD process chamber that can be cleaned according to an embodiment provided herein.

FIG. 5 is a schematic presentation of a system according to an embodiment provided herein.

FIG. 6 is a schematic presentation of a system according to an embodiment provided herein.

FIG. 7 is an experimental plot illustrating tin oxide etch rate as a function of process temperature using a cleaning method that does not employ a carbon-containing polymer removal step.

FIG. 8 is an experimental plot illustrating tin oxide etch rate as a function of process temperature using a cleaning method according to an embodiment provided herein.

### DETAILED DESCRIPTION OF THE PREFERRED EMBODIMENTS

Methods and apparatuses for cleaning tin oxide from process chambers are provided. Provided methods can be used for removal of tin oxide deposits from a variety of process chambers, including ALD process chambers, such as plasma enhanced ALD (PEALD) process chambers, CVD process chambers, such as plasma enhanced CVD (PECVD) process chambers, and PVD process chambers.

Tin oxide, as used herein, refers to a compound of tin and oxygen, typically having SnO₂ stoichiometry. Tin oxide layers and deposits that can be cleaned by provided methods, in some examples contain at least 90% SnO₂ by weight, such as at least 95% SnO₂ by weight.

Tin oxide is a versatile material that can be used in semiconductor device fabrication, for example, as a spacer or a mandrel during patterning. Tin oxide can be deposited on the semiconductor substrate by ALD, CVD, or PVD methods, and can be inadvertently deposited on the interior portions of the process chambers, such as on chamber walls and showerheads. Cleaning of tin oxide deposits in the process chambers presents several problems, which can be associated with damage to chamber parts or with incomplete removal of tin oxide.

Methods provided herein can be used for removing tin oxide deposits from a variety of chamber surfaces, such as from metallic chamber surfaces (e.g., from aluminum chamber surfaces), without damaging the surfaces. The methods compare favorably to chlorine-based cleaning methods, because chlorine-based chemistries can damage metallic chamber walls (e.g., aluminum chamber walls) during tin oxide removal. Provided methods also compare favorably to H₂-based etching, because hydrogen-based cleaning chemistries can lead to formation of a powder in the process chamber due to by-product decomposition.

Tin oxide can be removed (converted to a volatile compound) by exposing the tin oxide layer to a mixture of H₂ and a hydrocarbon (e.g., CH₄) with plasma activation. However, it was discovered that this cleaning chemistry can lead to formation of a non-volatile carbon-containing polymer on the surface of the tin oxide layer, which impedes tin oxide etching and leads to incomplete removal of tin oxide. Provided methods address this problem by periodically removing the carbon-containing polymer during tin oxide removal. The formation of the carbon-containing polymer is particularly pronounced at lower temperatures (such as at temperatures of less than about 140° C.). Therefore, provided methods are particularly valuable at lower temperatures, and can be conducted, for example, at temperatures of less than about 140° C., such as less than about 120° C., e.g., at about 30-120° C. or 80-120° C., where the temperatures are measured at the substrate support. The term “about” when used in reference to numerical values includes a range of 10% of the recited numerical value, unless otherwise specified.

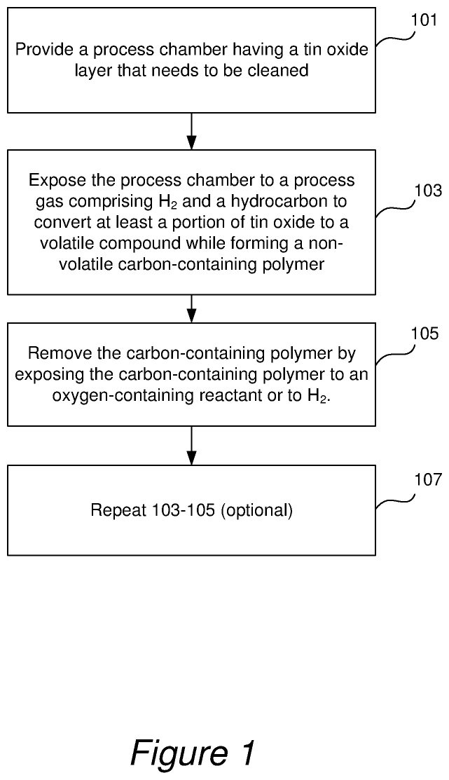

FIG. 1 is a process flow diagram illustrating an embodiment of the tin oxide cleaning methods. The process starts in step 101 by providing a process chamber having a tin oxide layer. The tin oxide layer may reside on various parts of the chamber, such as on chamber walls, on showerhead, or on parts of a substrate support. The process chamber may be a deposition process chamber (e.g., an ALD, CVD or PVD process chamber), which was used to deposit tin oxide on a semiconductor substrate (e.g., a wafer). In one example, tin oxide deposits on the chamber walls are formed when tin oxide is deposited on a semiconductor substrate by exposing the semiconductor substrate to a tin-containing precursor and an oxygen-containing precursor (e.g., in an ALD or CVD chamber). Exemplary tin-containing precursor can be, or include, organotin precursors such as, tetraethyl tin (SnEt₄), tetramethyl tin (SnMe₄), tetrakis(dimethylamino)tin (Sn(NMe₂)₄), tetrakis(diethylamido)tin (Sn(NEt₂)₄), tetrakis(ethylmethylamino)tin (Sn(NMeEt)₄), (dimethylamino)trimethyltin(IV) (Me₃Sn(NMe₂)), dibutyltin diacetate (Bu₂Sn(OAc)₂), Sn(II)(1,3-bis(1,1-dimethylethyl)-4,5-dimethyl-(4R,5R)-1,3,2-diazastannolidin-2-ylidene), N², N³-di-tert-butyl-butane-2,3-diamino-tin(II), and the like. Additional examples of organotin precursors include: bis[bis(trimethylsilyl)amino]tin(II)

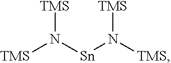 [SMILES: C[Si](C)(C)[N]([Sn][N]([Si](C)(C)C)[Si](C)(C)C)[Si](C)(C)C]

where TMS is trimethylsilyl,

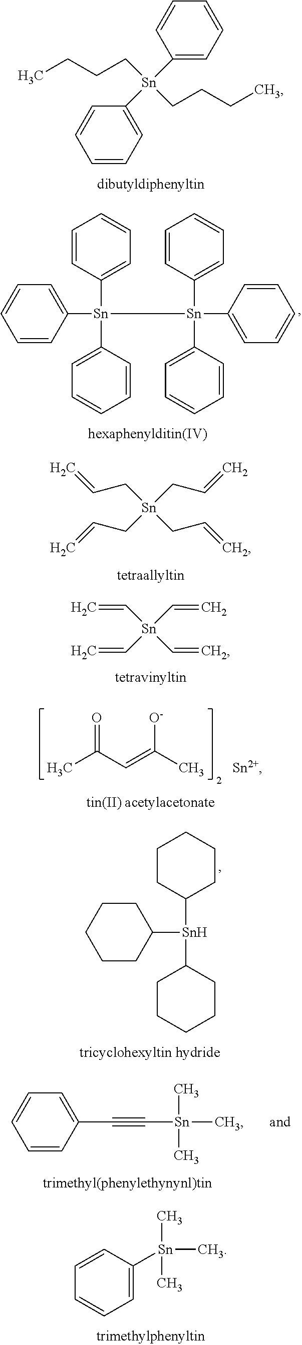

In another example, tin-containing precursors can also be inorganic tin precursors, such as, tin halides (e.g., SnF₂, SnCl₄, SnBr₄), tin hydrides (e.g., SnH₄), and the like. In some embodiments chlorinated organotin precursors are used such as trimethyltin chloride

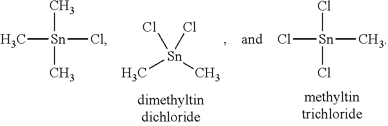

Exemplary oxygen-containing precursor can include, but is not limited to, oxygen (O₂), ozone (O₃), hydrogen peroxide (H₂O₂), and the like. When the chamber is prepared for cleaning, the semiconductor substrate is removed from the process chamber.

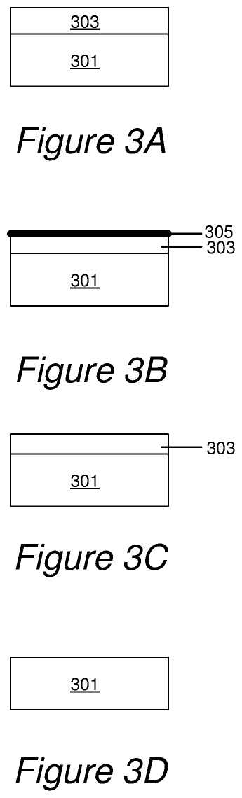

A schematic presentation of a portion of a process chamber having a tin oxide deposit is illustrated in FIG. 3A. The portion of a process chamber 301 may be made of any suitable chamber material such as metal (e.g., aluminum). In a specific example the portion of a process chamber 301 is a portion of an aluminum chamber wall of an ALD process chamber. The tin oxide layer 303 has formed on the portion of a process chamber 301 typically after sequential tin oxide deposition has been carried out on several semiconductor substrates. In some embodiments, the tin oxide layer 303 has a thickness of about 0.5-10 microns.

Referring to the process flow diagram of FIG. 1, the cleaning process follows in step 103 by exposing the process chamber to a process gas that includes H₂ and a hydrocarbon to convert at least a portion of tin oxide to a volatile compound while forming a carbon-containing polymer. In some embodiments, the process gas is activated in a plasma. In one example a mixture of H₂ and a hydrocarbon (e.g., methane, ethane, propane, cyclopropane, or butane) is introduced into the process chamber and is activated with a plasma to react with the tin oxide layer. At least a portion of the tin oxide is etched by being converted to a volatile compound which can be easily removed from the process chamber, but a non-volatile carbon-containing polymer is formed under certain conditions (e.g., at a temperature of less than about 140° C.). The resulting structure is illustrated in FIG. 3B, which illustrates that the thickness of the tin oxide layer 303 is reduced after etching step, but a layer of a carbon-containing polymer 305 is formed over the tin oxide layer 303. The carbon-containing polymer layer 305 impedes further etching of tin oxide layer 303 by the mixture of hydrogen and hydrocarbon. In some embodiments the tin oxide etching step 103 removes between about 0.1-0.25 microns of tin oxide.

Next, in step 105, the carbon-containing polymer is removed by exposing the carbon-containing polymer to an oxygen-containing reactant, or to H₂ in an absence of hydrocarbon. Both oxygen-containing reactants and H₂ are capable of converting the carbon-containing polymer to volatile compounds. For example, the oxygen-containing reactant may convert the carbon-containing polymer to CO₂ and/or CO. Examples of oxygen-containing reactants include dioxygen (O₂), ozone (O₃), and hydrogen peroxide (H₂O₂). This step may be performed either thermally (in an absence of plasma) or with plasma activation. For example, plasma-activated O₂ may be used to remove the carbon-containing polymer. In other embodiments ozone or hydrogen peroxide are used without plasma activation to remove the carbon-containing polymer. When H₂ is used to remove the carbon-containing polymer, it is introduced into the process chamber without a hydrocarbon. For example, a gas consisting essentially of H₂ (with or without an inert gas diluent) may be used, where the reaction with the carbon-containing polymer may be optionally assisted with a plasma. The structure formed after removal of the carbon-containing polymer is shown in FIG. 3C. In the illustrated embodiment it is shown that a portion of tin oxide layer 303 remains on the portion of the chamber 301. It is understood, that in some embodiments, if the initial tin oxide layer is thin, one cycle that includes one tin oxide removal step 103 and one carbon-containing polymer removal step 105, may be sufficient for chamber cleaning. However, for thicker tin oxide layers, one cycle may not be sufficient and multiple cycles are performed.

When one cycle containing one step 103 followed by one step 105 is not sufficient to remove all of tin oxide, then, as shown in step 107, steps 103 and 105 are repeated. In some embodiments steps 103 and 105 are repeated multiple times, until all tin oxide is removed from the surfaces of the process chamber. In some implementations the cleaning process includes performing between about 4-10 cycles, where each cycle includes one tin oxide removal step 103 and one carbon-containing polymer removal step 105. The structure obtained after multiple cycles is shown in FIG. 3D, where tin oxide layer 303 is completely removed from the portion of the process chamber 301.

It is noted that the process chamber may be purged after each of the steps 103 and 105 to remove the volatile reaction products. For example, purging can be performed with an inert gas, such as N₂, helium, argon, etc.

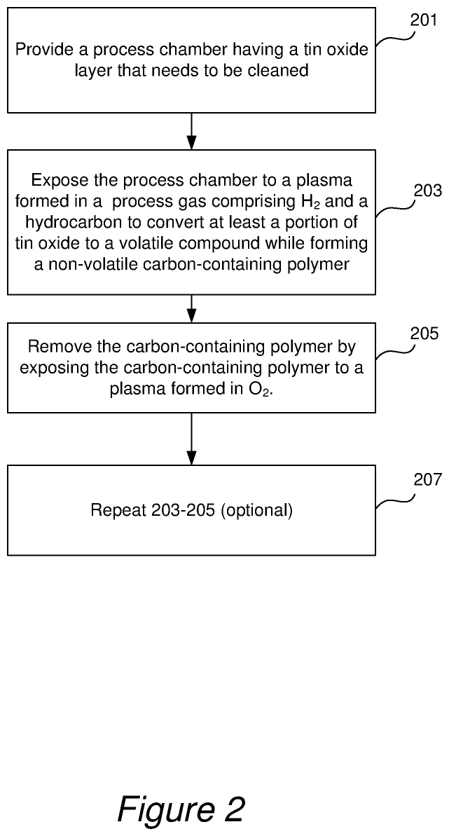

FIG. 2 is a process flow diagram illustrating one exemplary embodiment of the cleaning method. In step 201, a process chamber having a tin oxide layer is provided. In a specific example, the process chamber is a PEALD process chamber. In step 203, the process chamber is exposed to a plasma formed in a process gas that includes a hydrocarbon and H₂ to convert at least a portion of the tin oxide layer to a volatile compound while forming a carbon-containing polymer. In one embodiment the molar ratio of H₂ to hydrocarbon (e.g., CH₄) is about 1 to 20 (and in some embodiments is between about 1:15-1:25). The hydrogen and hydrocarbon in some embodiments are introduced with an inert carrier gas, such as Ar, He, or N2. The flow rate of the inert carrier gas can range from about 0-90% (e.g., 5-80%) of the total gas flow. The plasma is generated in the process chamber or remotely and then introduced into the process chamber. In one embodiment RF frequency of between about 100 kHz-30 MHz, is used for plasma generation, with a power in a range of between about 50-400 W. This step can convert tin oxide to a volatile tin hydride and/or to a volatile organometallic tin compound, which can be removed from the process chamber by purging, e.g., with an inert gas, such as He, Ar, or N₂.

Next, in step 205, the carbon-containing polymer is removed by exposing the carbon-containing polymer to a plasma formed in O₂. In one example, O₂ is introduced into the process chamber, either alone, or with an inert carrier gas (e.g., He, Ar, or N₂), and the plasma is formed either directly in the process chamber or remotely and is fed to the process chamber. RF frequency of between about 100 kHz-30 MHz and power of between about 50-400 W is used in some embodiments in this step.

Next, in step 207, if tin oxide remains in the process chamber, steps 203 and 205 are repeated. In some implementations, the cleaning method includes performing 4-10 cycles, where each cycle includes one tin oxide removal step 203 and one carbon-containing polymer removal step 207. The temperature and pressure for each of the steps 203 and 205 may be the same or different. In one implementation the entire cleaning process is performed at a substantially constant temperature from a range of about 30-140° C., such as 30-120° C., or 80-120° C. The pressure for each of the steps 203 and 205 can be in a range of between about 0.1-20 Torr, such as between about 0.5-6.0 Torr. The flow rates of process gases depend on the size of the process chamber and can range, for example, from about 100 to 20,000 sccm.

The methods described herein are used for cleaning tin oxide in process chambers. In alternative embodiments, the methods can be used for etching tin oxide layers on other substrates, such as on semiconductor substrates. For example, the processes described with reference to FIG. 1, FIG. 2 and FIGS. 3A-3D can be used for etching tin oxide on a semiconductor wafer. For example, in some embodiments the process starts by providing a semiconductor substrate having a tin oxide layer deposited thereon (e.g., a tin oxide mandrel or a tin oxide spacer). For example, the tin oxide layer may be deposited by CVD or ALD using a reaction between a tin-containing precursor and an oxygen-containing precursor as described herein. Next, the semiconductor substrate is exposed to a process gas that includes H₂ and a hydrocarbon, where the process gas may be activated in a plasma to convert at least a portion of the tin oxide layer to a volatile compound, while forming a non-volatile carbon-containing polymer. In this step at least a portion of tin oxide is removed from the surface of the substrate. Next the substrate is exposed to an oxygen-containing reactant (e.g., O₂ in a plasma) or to H₂ in an absence of a hydrocarbon to remove the carbon-containing polymer. After removal of the carbon-containing polymer these steps may be repeated as many times as necessary to etch a desired amount of tin oxide.

In some embodiments, the method further includes applying the photoresist to the semiconductor substrate; exposing the photoresist to light; patterning the photoresist and transferring the pattern to the semiconductor substrate; and selectively removing the photoresist from the semiconductor substrate. In some embodiments the photoresist is applied prior to tin oxide exposure to hydrogen and hydrocarbon, thereby forming a substrate, where the photoresist layer overlies the tin oxide layer (but is not necessarily in contact with the tin oxide layer). In some embodiments, the pattern is transferred from the photoresist to the semiconductor substrate prior to tin oxide exposure to hydrogen and hydrocarbon. In some embodiments transferring the pattern to the semiconductor substrate comprises tin oxide exposure to hydrogen and hydrocarbon and etching, as described herein.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The disclosed implementations can be implemented on a semiconductor wafer, such as on a 200 mm, 300 mm, or 450 mm semiconductor wafer. However, the disclosed implementations are not so limited. The semiconductor wafer may be of various shapes, sizes, and materials. In addition to semiconductor wafers, other types of work pieces may take advantage of the disclosed implementations including various articles such as printed circuit boards and the like.

### Apparatus

Provided methods can be performed in a variety of process chambers, including ALD, CVD, and PVD process chambers. For example, provided methods can be implemented in a Striker® ALD apparatus available from Lam Research, Fremont, Calif. In one implementation, an apparatus is provided, where the apparatus includes a process chamber having an inlet for introducing a process gas and a controller having program instructions configured to cause execution of all method steps described herein. For example the controller may include program instructions configured to cause exposure of the process chamber having a layer of tin oxide to a process gas that includes H₂ and a hydrocarbon to convert tin oxide to a volatile compound while forming a carbon-containing polymer, and to cause subsequent removal of the carbon-containing polymer by exposing the carbon-containing polymer to an oxygen-containing reactant (e.g., to O₂ in a plasma) or to H₂ in an absence of a hydrocarbon. The apparatus may also include a system for generating a plasma, and a heater for maintaining a desired temperature throughout the cleaning process.

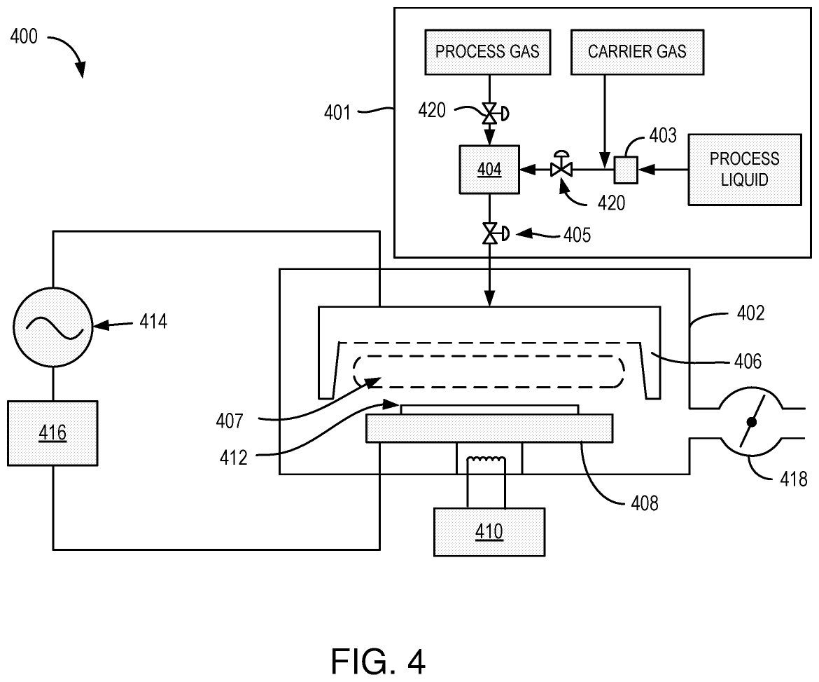

FIG. 4 schematically shows an embodiment of a process station 400 that may be used to deposit material (e.g., tin oxide) using atomic layer deposition (ALD) and/or chemical vapor deposition (CVD), either of which may be plasma enhanced. The process station 400 may be cleaned from tin oxide deposits using methods provided herein. For simplicity, the process station 400 is depicted as a standalone process station having a process chamber body 402 for maintaining a low-pressure environment. However, it will be appreciated that a plurality of process stations 400 may be included in a common process tool environment. Further, it will be appreciated that, in some embodiments, one or more hardware parameters of process station 400, including those discussed in detail below, may be adjusted programmatically by one or more computer controllers.

Process station 400 fluidly communicates with reactant delivery system 401 for delivering process gases to a distribution showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Similarly, a showerhead inlet valve 405 may control introduction of process gasses to the showerhead 406.

Some reactants used during ALD deposition, may be stored in liquid form prior to vaporization at and subsequent delivery to the process station. For example, the embodiment of FIG. 4 includes a vaporization point 403 for vaporizing liquid reactant to be supplied to mixing vessel 404. In some embodiments, vaporization point 403 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller upstream of vaporization point 403 may be provided for controlling a mass flow of liquid for vaporization and delivery to process station 400. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller. In some implementations the apparatus includes a vessel for holding a liquid precursor (e.g., an organotin compound) and a conduit that allows the precursor vapor to be carried into the process chamber with an inert carrier gas (e.g., Ar, He, or N₂)

Showerhead 406 distributes process gases toward substrate 412 during deposition. In the embodiment shown in FIG. 4, substrate 412 is located beneath showerhead 406, and is shown resting on a pedestal 408. It is understood that during cleaning the substrate is removed from the process chamber. It will be appreciated that showerhead 406 may have any suitable shape, and may have any suitable number and arrangement of ports for distributing processes gases to substrate 412 or for distributing process gases during cleaning operations.

In some embodiments, a microvolume 407 is located beneath showerhead 406. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. The use of microvolume significantly reduces the cycle time because of faster purge, and higher precursor partial pressure in the microvolume.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition process phase, pedestal 408 may be raised to position substrate 412 within microvolume 407. In some embodiments, microvolume 407 may completely enclose substrate 412 as well as a portion of pedestal 408 to create a region of high flow impedance during a deposition process.

Optionally, pedestal 408 may be lowered and/or raised during portions of the deposition or cleaning process to modulate process pressure, reactant concentration, etc., within microvolume 407. In one scenario where process chamber body 402 remains at a base pressure during the deposition process, lowering pedestal 408 may allow microvolume 407 to be evacuated. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers.

Returning to the embodiment shown in FIG. 4, showerhead 406 and pedestal 408 electrically communicate with RF power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 408 may be temperature controlled via heater 410. Further, in some embodiments, pressure control for deposition process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to process station 400.

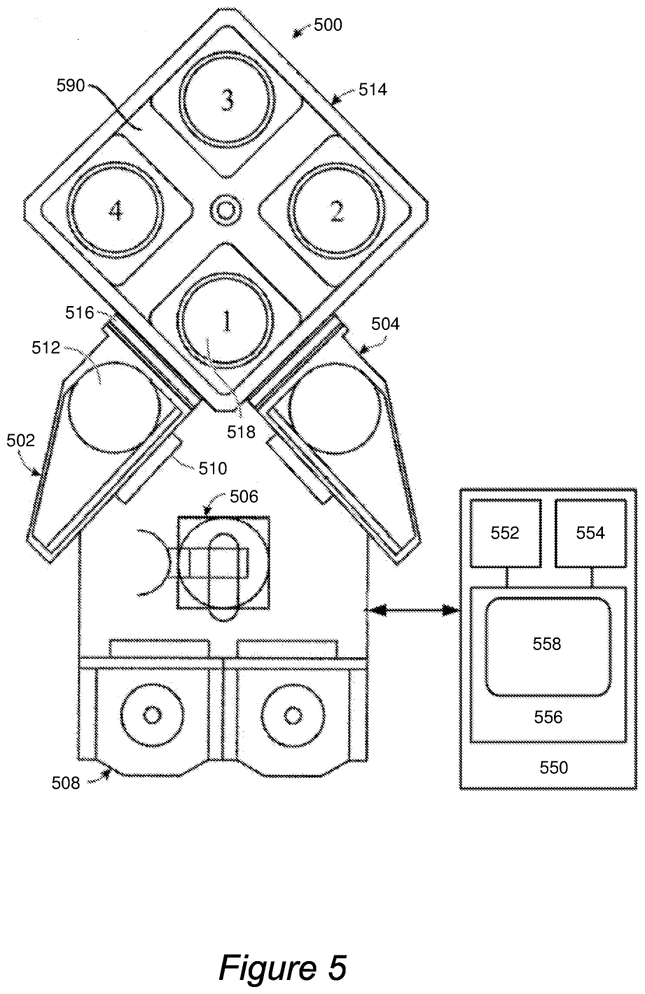

FIG. 5 shows a schematic view of an embodiment of a multi-station processing tool 500 with an inbound load lock 502 and an outbound load lock 504, either or both of which may comprise a remote plasma source. A robot 506, at atmospheric pressure, is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 comprises a remote plasma source, the wafer may be exposed to a remote plasma treatment in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 5 includes load locks, it will be appreciated that, in some embodiments, direct entry of a wafer into a process station may be provided.

The depicted processing chamber 514 comprises four process stations, numbered from 1 to 4 in the embodiment shown in FIG. 5. Each station has a heated pedestal (shown at 518 for station 1), and gas line inlets. It will be appreciated that in some embodiments, each process station may have different or multiple purposes. While the depicted processing chamber 514 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 5 also depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non-limiting examples include wafer carousels and wafer handling robots. FIG. 5 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. System control software 558 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 500. System control software 558 may be configured in any suitable way. For example, various process tool component subroutines or control objects may be written to control operation of the process tool components necessary to carry out various process tool processes in accordance with the disclosed cleaning methods. System control software 558 may be coded in any suitable computer readable programming language.

In some embodiments, system control software 558 may include input/output control (IOC) sequencing instructions for controlling the various parameters described above. For example, each phase of a cleaning process may include one or more instructions for execution by system controller 550. The instructions for setting process conditions for a cleaning process phase may be included in a corresponding cleaning recipe phase.

Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling gas composition and flow rates and optionally for flowing gas into one or more process stations prior to deposition or cleaning in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, the STRIKER® product family and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

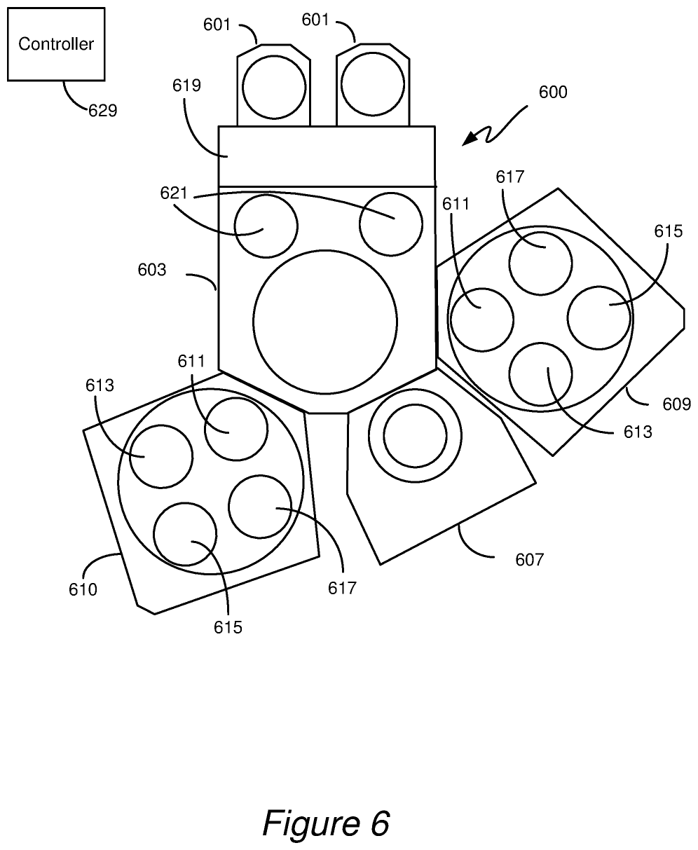

FIG. 6 is a block diagram of a processing system suitable for conducting tin oxide film deposition processes that can be cleaned in accordance with certain embodiments. The system 600 includes a transfer module 603. The transfer module 603 provides a clean, pressurized environment to minimize risk of contamination of substrates being processed as they are moved between various reactor modules. Mounted on the transfer module 603 are two multi-station reactors 609 and 610, each capable of performing atomic layer deposition (ALD) and/or chemical vapor deposition (CVD) according to certain embodiments. Reactors 609 and 610 may include multiple stations 611, 613, 615, and 617 that may sequentially or non-sequentially perform deposition operations and may be cleaned in accordance with disclosed embodiments. The stations may include a heated pedestal or substrate support, one or more gas inlets or showerhead or dispersion plate.

Also mounted on the transfer module 603 may be one or more single or multi-station modules 607 capable of performing plasma or chemical (non-plasma) pre-cleans. The module 607 may in some cases be used for various treatments to, for example, prepare a substrate for a deposition process. The module 607 may also be designed/configured to perform various other processes such as etching or polishing. The system 600 also includes one or more wafer source modules 601, where wafers are stored before and after processing. An atmospheric robot (not shown) in the atmospheric transfer chamber 619 may first remove wafers from the source modules 601 to loadlocks 621. A wafer transfer device (generally a robot arm unit) in the transfer module 603 moves the wafers from loadlocks 621 to and among the modules mounted on the transfer module 603.

In various embodiments, a system controller 629 is employed to control process conditions during deposition and cleaning. The controller 629 will typically include one or more memory devices and one or more processors. A processor may include a CPU or computer, analog and/or digital input/output connections, stepper motor controller boards, etc.

The controller 629 may control all of the activities of the deposition apparatus. The system controller 629 executes system control software, including sets of instructions for controlling the timing, mixture of gases, chamber pressure, chamber temperature, temperature, radio frequency (RF) power levels, wafer chuck or pedestal position, and other parameters of a particular process. Other computer programs stored on memory devices associated with the controller 629 may be employed in some embodiments.

Typically there will be a user interface associated with the controller 629. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 629. The signals for controlling the process are output on the analog and digital output connections of the deposition apparatus 600.

The system software may be designed or configured in many different ways. For example, various chamber component subroutines or control objects may be written to control operation of the chamber components necessary to carry out the deposition and cleaning processes in accordance with the disclosed embodiments. Examples of programs or sections of programs for this purpose include substrate positioning code, process gas control code, pressure control code, and heater control code.

In some implementations, a controller 629 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Experimental Examples

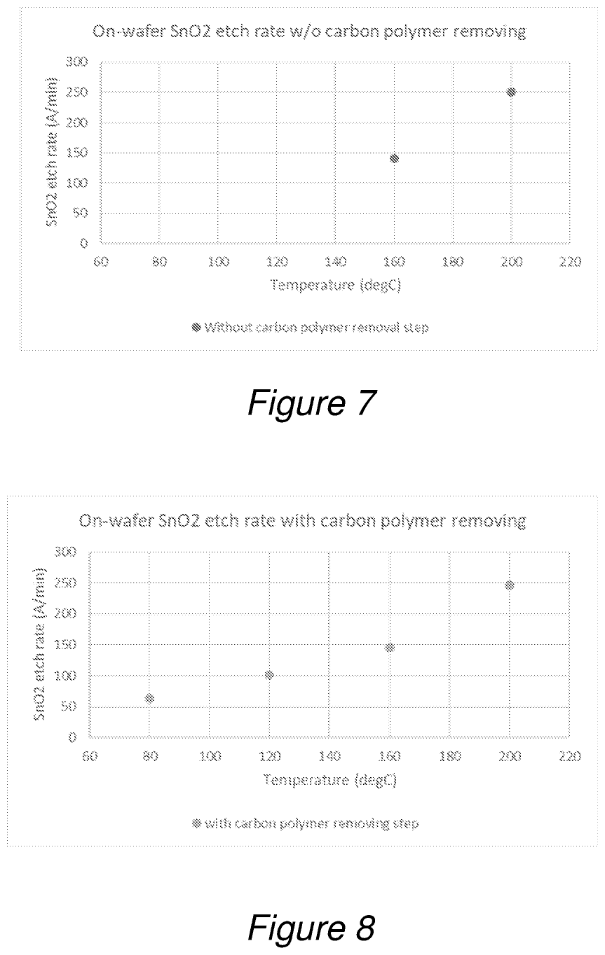

Tin oxide removal methods were tested using a tin oxide layer deposited on a semiconductor wafer. In a control experiment tin oxide was etched using only a mixture of H₂ and CH₄ in a plasma. Tin oxide was etched at appreciable rates only at high temperatures of between 160° C., and 200° C. FIG. 7 is a plot illustrating a dependence of etch rates on etch temperature for this etch chemistry. Etching stalled at lower temperatures due to formation of a non-volatile carbon-containing polymer.

In another experiment tin oxide was etched in accordance with an embodiment provided herein. Tin oxide was etched by using alternating exposure of the substrate to (a) a plasma formed in a mixture of H₂ and CH₄, followed by (b) a plasma formed in O₂. Oxygen plasma exposure resulted in removal of the carbon-containing polymer, which lead to appreciable tin oxide removal rates even at lower temperatures. Specifically, it was possible to remove tin oxide at low temperatures of 80° C., and 120° C. FIG. 8 is a plot illustrating a dependence of etch rates on etch temperature for the described etching method, in accordance to an embodiment provided herein. It can be seen that with the use of provided methods, tin oxide can be successfully etched at significantly lower temperatures compared to the control chemistry that does not employ the carbon-containing polymer removal step.

The carbon-containing polymer was visually observed on a process chamber showerhead after H₂/CH₄ plasma clean that did not employ the carbon-containing polymer removal step. When O₂ plasma treatment step was added after the H₂/CH₄ plasma clean step, the carbon-containing polymer was no longer visibly observed on the showerhead.

### FURTHER IMPLEMENTATIONS

The apparatus and processes described herein, such as tin oxide etching on semiconductor substrates using provided methods, may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or eUV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

1. A method of cleaning a process chamber, the method comprising:
(a) providing a process chamber having a layer of tin oxide on at least some parts of the process chamber;
(b) exposing the tin oxide layer in the process chamber to a process gas comprising a hydrocarbon and hydrogen (H₂) to convert at least a portion of the tin oxide layer to a volatile compound, wherein the exposure of the tin oxide layer to the process gas comprising a hydrocarbon and hydrogen (H₂) further results in a formation of a non-volatile carbon-containing polymer; and
(c) removing the carbon-containing polymer by exposing the carbon-containing residue to an oxygen-containing reactant or to H₂, wherein exposure to H₂ is performed in an absence of hydrocarbon.

2. The method of claim 1, wherein the carbon-containing polymer is removed in (c) by exposing the carbon-containing residue to the oxygen-containing reactant.

3. The method of claim 1, wherein the carbon-containing polymer is removed in (c) by exposing the carbon-containing residue to the oxygen-containing reactant selected from the group consisting of O₂, O₃, and H₂O₂.

4. The method of claim 1, wherein the oxygen-containing reactant is plasma-activated O₂.

5. The method of claim 1, wherein the oxygen-containing reactant is O₃.

6. The method of claim 1, further comprising repeating (b) and (c).

7. The method of claim 1, further comprising purging the process chamber after (b).

8. The method of claim 1, wherein the process chamber comprises metal parts.

9. The method of claim 1, wherein the process chamber comprises aluminum parts.

10. The method of claim 1, wherein the process chamber is selected from the group consisting of an ALD chamber, a CVD chamber, and a PVD chamber.

11. The method of claim 10, wherein the process chamber is a PEALD chamber or a PECVD chamber.

12. The method of claim 1, wherein (c) comprises exposing the carbon-containing polymer to a process gas consisting essentially of H₂ or consisting essentially of a mixture of H₂ and an inert gas in a plasma.

13. The method of claim 1, wherein (c) comprises heating the process chamber during removal of the carbon-containing polymer.

14. An apparatus for processing a semiconductor substrate, the apparatus comprising:
(a) a process chamber comprising an inlet for a process gas, and
(b) a controller comprising program instructions for cleaning the process chamber from a tin oxide layer, wherein the program instructions are configured to cause:
(i) an exposure of the tin oxide layer in the process chamber to a process gas comprising a hydrocarbon and hydrogen (H₂) to convert at least a portion of the tin oxide layer to a volatile compound, wherein the exposure of the tin oxide layer to the process gas comprising a hydrocarbon and hydrogen (H₂) further results in a formation of a non-volatile carbon-containing polymer; and
(ii) a removal of the carbon-containing residue by exposing the carbon-containing polymer to an oxygen-containing reactant or to H₂, wherein exposure to H₂ is performed in an absence of hydrocarbon.

15. The apparatus of claim 14, wherein the oxygen-containing reactant is selected from the group consisting of O₂, O₃, and H₂O₂.

16. The apparatus of claim 14, wherein the apparatus comprises a system for generating a plasma and wherein the program instructions for (ii) are configured to cause an exposure of the carbon-containing polymer to plasma-activated O₂.

17. The apparatus of claim 14, wherein the apparatus comprises a heater, and wherein the program instructions for (ii) are configured to cause an exposure of the carbon-containing polymer to plasma-activated O₂ in a heated process chamber.

18. The apparatus of claim 14, wherein the program instructions are further configured to repeat steps (i) and (ii).

19. A method for etching a tin oxide layer on a semiconductor substrate, the method comprising:
(a) providing a semiconductor substrate having an exposed layer of tin oxide;
(b) contacting the exposed tin oxide layer in a process chamber to a process gas comprising a hydrocarbon and hydrogen (H₂) to convert at least a portion of the tin oxide layer to a volatile compound, wherein the contacting of the tin oxide layer to the process gas comprising a hydrocarbon and hydrogen (H₂) further results in a formation of a non-volatile carbon-containing polymer; and
(c) removing the carbon-containing polymer by exposing the carbon-containing polymer to an oxygen-containing reactant or to H₂, wherein exposure to H₂ is performed in an absence of hydrocarbon.

20. The method of claim 19, further comprising:
applying photoresist to the semiconductor substrate prior to (b);
exposing the photoresist to light;
patterning the photoresist and transferring the pattern to the semiconductor substrate, wherein transferring the pattern to the semiconductor substrate is performed prior to (b), or wherein transferring the pattern to the semiconductor substrate comprises etching the tin oxide layer by exposing the semiconductor substrate to the process gas comprising the hydrocarbon and hydrogen in (b); and
selectively removing the photoresist from the semiconductor substrate.

21. The method of claim 19, further comprising, prior to (a), depositing the layer of tin oxide using a tin-containing precursor selected from the group consisting of SnF₂, SnCl₄, SnBr₄, SnH₄, tetraethyl tin (SnEt₄), tetramethyl tin (SnMe₄), tetrakis(dimethylamino)tin (Sn(NMe₂)₄), tetrakis(diethylamido)tin (Sn(NEt₂)₄), tetrakis(ethylmethylamino)tin (Sn(NMeEt)₄), (dimethylamino)trimethyltin(IV) (Me₃Sn(NMe₂)), dibutyltin diacetate (Bu₂Sn(OAc)₂), Sn(II)(1,3-bis(1,1-dimethylethyl)-4,5-dimethyl-(4R,5R)-1,3,2-diazastannolidin-2-ylidene), N², N³-di-tert-butyl-butane-2,3-diamino-tin(II), bis[bis(trimethylsilyl)amino]tin(II) 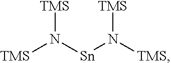 [SMILES: C[Si](C)(C)[N]([Sn][N]([Si](C)(C)C)[Si](C)(C)C)[Si](C)(C)C]
where TMS is trimethylsilyl,

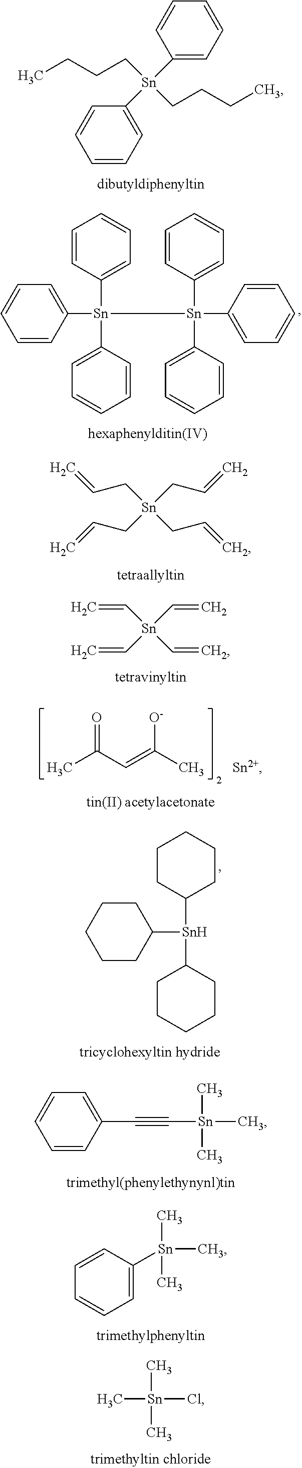

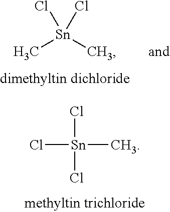

22. The method of claim 19, further comprising, prior to (a), depositing the layer of tin oxide using a tin-containing precursor selected from the group consisting of tetramethyl tin (SnMe₄), tetraethyl tin (SnEt₄), tetrakis(dimethylamino)tin, and (dimethylamino)trimethyl tin(IV).

23. An apparatus for processing a semiconductor substrate, the apparatus comprising:
(a) a process chamber comprising an inlet for a process gas and a substrate support for holding a semiconductor substrate in place; and
(b) a controller comprising program instructions for etching a tin oxide layer on the semiconductor substrate, wherein the program instructions are configured to cause:
(i) contacting of the tin oxide layer on the semiconductor substrate to a process gas comprising a hydrocarbon and hydrogen (H₂) to convert at least a portion of the tin oxide layer to a volatile compound, wherein the exposure of the tin oxide layer to the process gas comprising a hydrocarbon and hydrogen (H₂) further results in a formation of a non-volatile carbon-containing polymer; and
(ii) removal of the carbon-containing residue by exposing the carbon-containing polymer to an oxygen-containing reactant or to H₂, wherein exposure to H₂ is performed in an absence of hydrocarbon.
